(19) United States
(12) Patent Application Publication
(10) Pub. No.: US 2024/0363606 A1
(43) Pub. Date: Oct. 31, 2024

(54) SEMICONDUCTOR DEVICE

(71) Applicant: ROHM CO., LTD., Kyoto-shi (JP)

(72) Inventors: Yoshizo OSUMI, Kyoto-shi (JP); Tsunehisa ONO, Kyoto-shi (JP)

(21) Appl. No.: 18/768,925

(22) Filed: Jul. 10, 2024

Related U.S. Application Data
(63) Continuation of application No. PCT/JP2022/046905, filed on Dec. 20, 2022.

(30) Foreign Application Priority Data
Jan. 11, 2022 (JP) 2022-002413

(51) Int. Cl. H01L 25/16; H01L 23/00; H01L 23/31; H01L 23/495; H01L 23/64

(52) U.S. Cl. CPC H01L 25/16; H01L 23/3107; H01L 23/49558; H01L 23/645; H01L 24/45; H01L 24/48; H01L 2224/45124; H01L 2224/45144; H01L 2224/45147; H01L 2224/48195; H01L 2224/48245; H01L 2924/1426; H01L 2924/19042; H01L 2924/19043

(57) ABSTRACT

The semiconductor device includes an insulating element, a conductive member, a sealing resin, and a discharge path. The conductive member includes a first terminal and a second terminal that are electrically connected to the insulating element. The sealing resin includes a resin first surface and a resin second surface. The first terminal protrudes from the resin first surface. The resin second surface faces away from the resin first surface in a first direction perpendicular to a thickness direction of the insulating element. The second terminal protrudes from the resin second surface. The discharge path is a conductive path between the first terminal and the second terminal, and is electrically conductive at a voltage lower than a dielectric withstand voltage of the insulating element.

### TECHNICAL FIELD

The present disclosure relates to a semiconductor device.

### BACKGROUND ART

An inverter used in an electric vehicle, a hybrid vehicle, or a home appliance, for example, is provided with a semiconductor device having an insulating element. The inverter may include the semiconductor device and power semiconductors such as insulated gate bipolar transistors (IGBTs) or metal oxide semiconductor field effect transistors (MOSFETs). The semiconductor device includes a control element, the insulating element, and a drive element. The inverter supplies a control signal received from an engine control unit (ECU) to the control element of the semiconductor device. The control element converts the control signal into a pulse width modulation (PWM) control signal, and transmits the resulting signal to the drive element via the insulating element. According to the PWM control signal, the drive element switches the power semiconductors at desired timings. Six power semiconductors are switched at desired timings, whereby three-phase AC power for motor driving is generated from the DC power of a vehicle battery. For example, JP-A-2016-207714 discloses an example of a semiconductor device with an insulating element.

### BRIEF DESCRIPTION OF THE DRAWINGS

FIG. 1 is a plan view showing a semiconductor device according to a first embodiment of the present disclosure.

FIG. 2 is a plan view showing the semiconductor device in FIG. 1, as seen through a sealing resin.

FIG. 3 is a front view showing the semiconductor device in FIG. 1.

FIG. 4 is a left-side view showing the semiconductor device in FIG. 1.

FIG. 5 is a partially enlarged view of FIG. 2.

FIG. 6 is a cross-sectional view along line VI-VI in FIG. 2.

FIG. 7 is a cross-sectional view along line VII-VII in

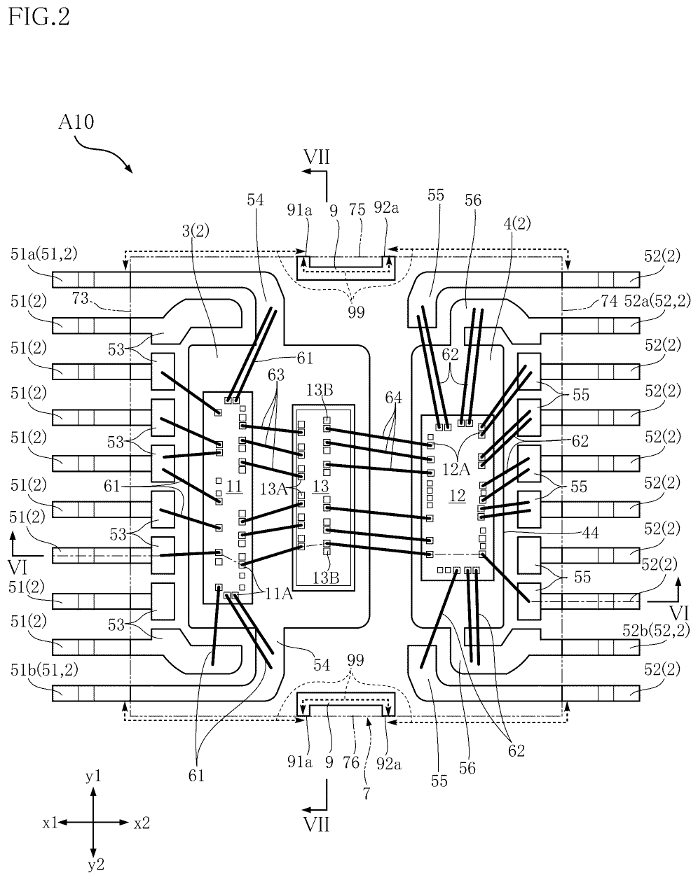

FIG. 2.

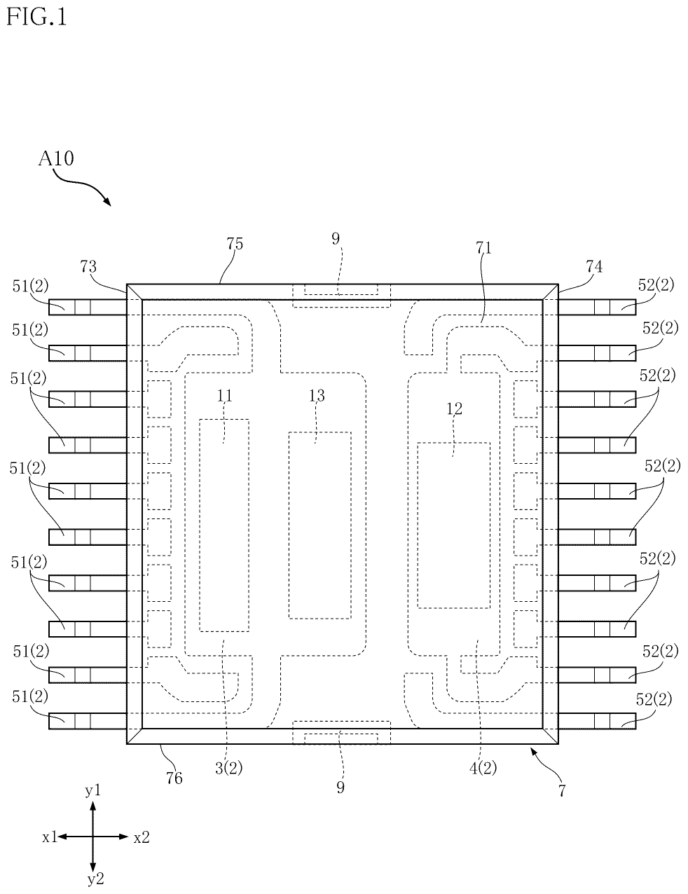

FIG. 8 is a plan view showing a step of a method for manufacturing the semiconductor device in FIG. 1.

FIG. 9 is a plan view showing a step of the method for manufacturing the semiconductor device in FIG. 1.

FIG. 10 is a plan view showing a semiconductor device according to a first variation of the first embodiment, as seen through a sealing resin.

FIG. 11 is a plan view showing a semiconductor device according to a second variation of the first embodiment, as seen through a sealing resin.

FIG. 12 is a plan view showing a semiconductor device according to a third variation of the first embodiment, as seen through a sealing resin.

FIG. 13 is a plan view showing a semiconductor device according to a fourth variation of the first embodiment.

FIG. 14 is a cross-sectional view along line XIV-XIV in FIG. 13.

FIG. 15 is a plan view showing a semiconductor device according to a second embodiment of the present disclosure, as seen through a sealing resin.

FIG. 16 is a plan view showing a semiconductor device according to a third embodiment of the present disclosure, as seen through a sealing resin.

FIG. 17 is a partially enlarged view of FIG. 16.

FIG. 18 is a cross-sectional view along line XVIII-XVIII in FIG. 16.

FIG. 19 is a partially enlarged plan view showing a semiconductor device according to a first variation of the third embodiment.

FIG. 20 is a cross-sectional view showing the semiconductor device in FIG. 19.

FIG. 21 is a partially enlarged plan view showing a semiconductor device according to a second variation of the third embodiment.

FIG. 22 is a cross-sectional view showing the semiconductor device in FIG. 21.

FIG. 23 is a plan view showing a semiconductor device according to a fourth embodiment of the present disclosure, as seen through a sealing resin.

### DETAILED DESCRIPTION OF EMBODIMENTS

The following describes preferred embodiments according to the present disclosure with reference to the drawings.

### First Embodiment

FIGS. 1 to 7 show an example of a semiconductor device according to the present disclosure. A semiconductor device A10 of the present embodiment includes a first semiconductor element 11, a second semiconductor element 12, an insulating element 13, a conductive member 2, a plurality of wires 61 to 64, a sealing resin 7, and a pair of discharge portions 9. The conductive member 2 includes a first die pad 3, a second die pad 4, a plurality of first terminals 51, a plurality of second terminals 52, a plurality of pad portions 53 and 55, a pair of connecting portions 54, and a pair of connecting portions 56. The semiconductor device A10 is surface-mountable on the wiring board of an inverter such as an electric vehicle or a hybrid vehicle. The use and function of the semiconductor device A10 are not particularly limited. The semiconductor device A10 is provided in a small outline package (SOP). However, the package type of the semiconductor device A10 is not limited to an SOP.

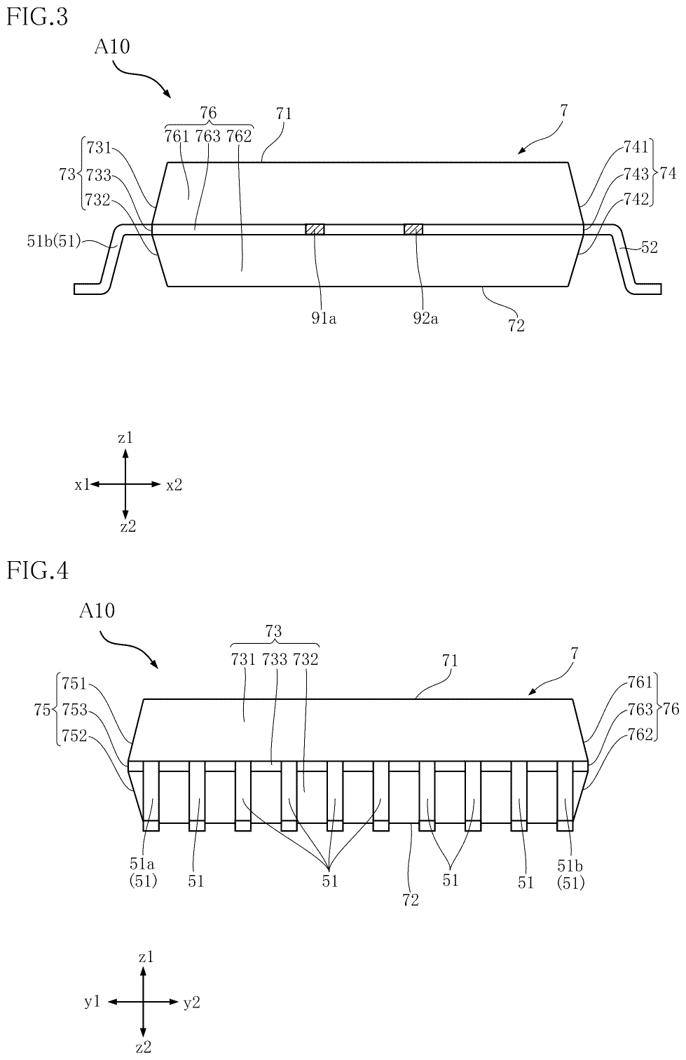

FIG. 1 is a plan view showing the semiconductor device A10. FIG. 2 is a plan view showing the semiconductor device A10. For convenience of understanding, FIG. 2 shows the sealing resin 7 in phantom, and the outline of the sealing resin 7 is indicated by an imaginary line (two-dot chain line). FIG. 3 is a front view showing the semiconductor device A10.

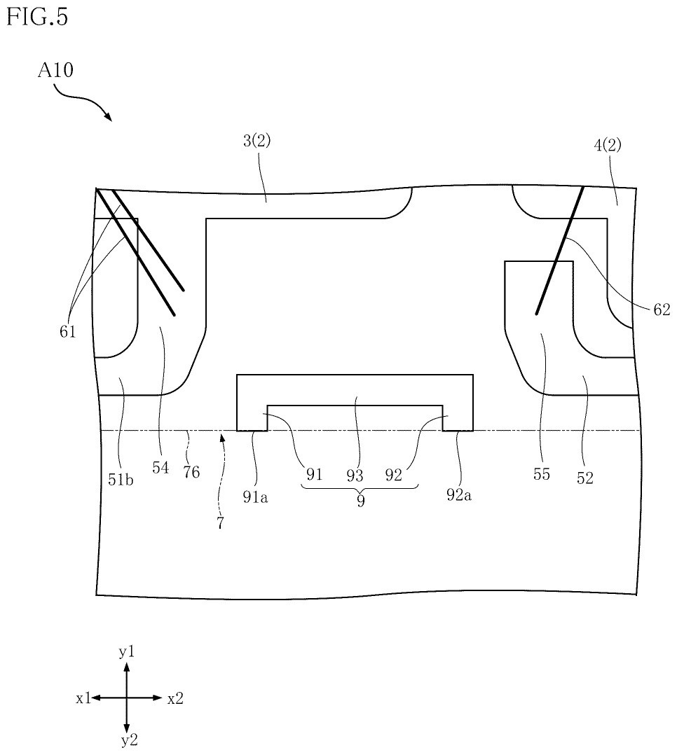

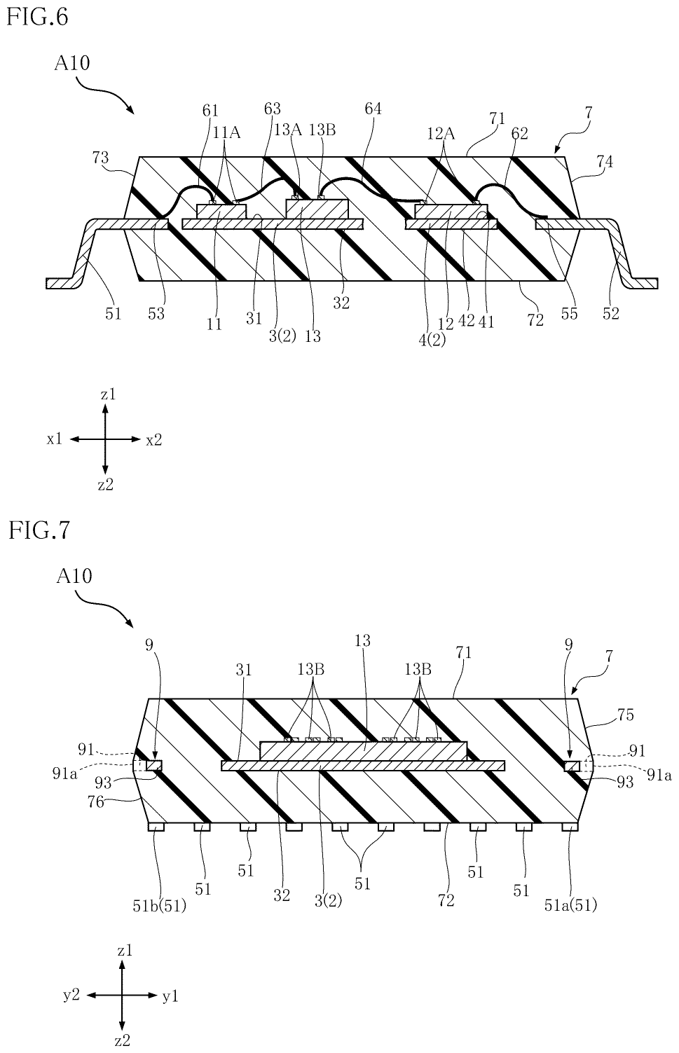

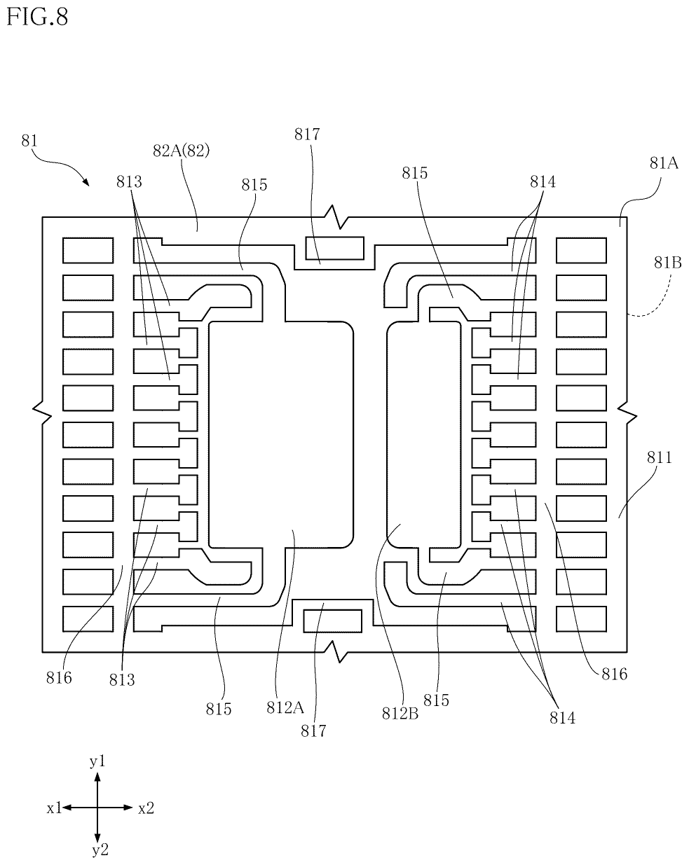

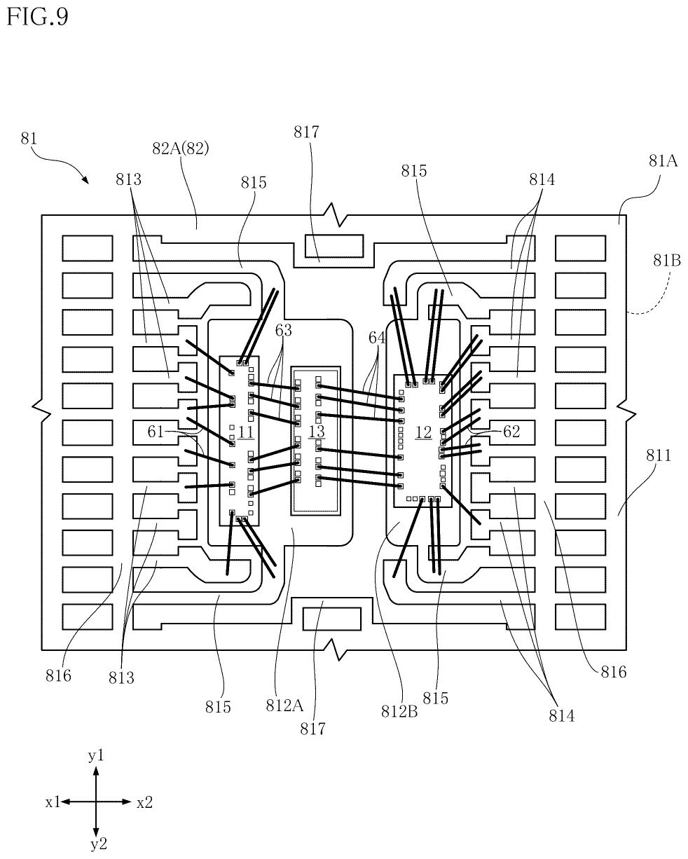

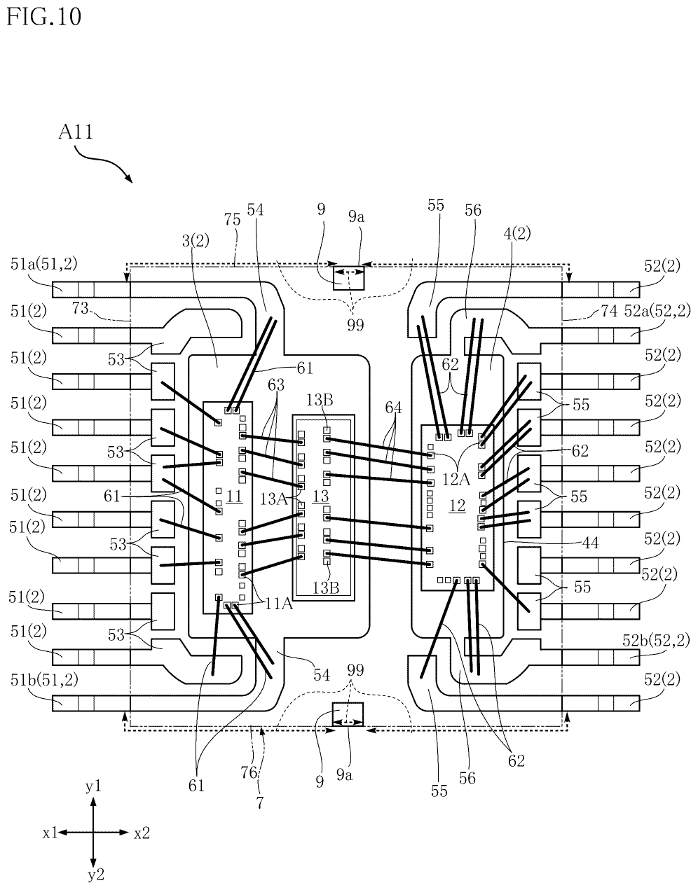

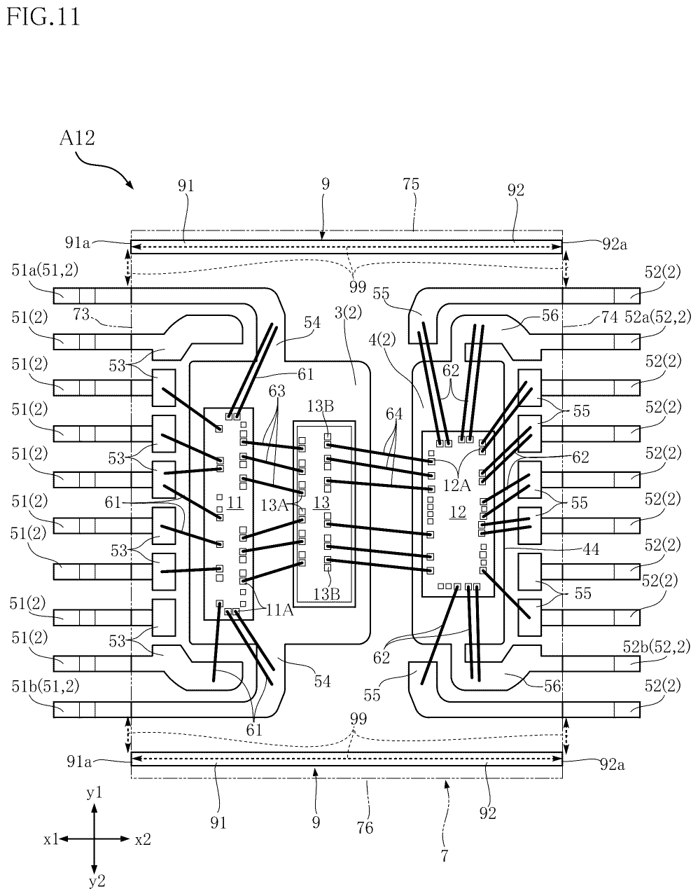

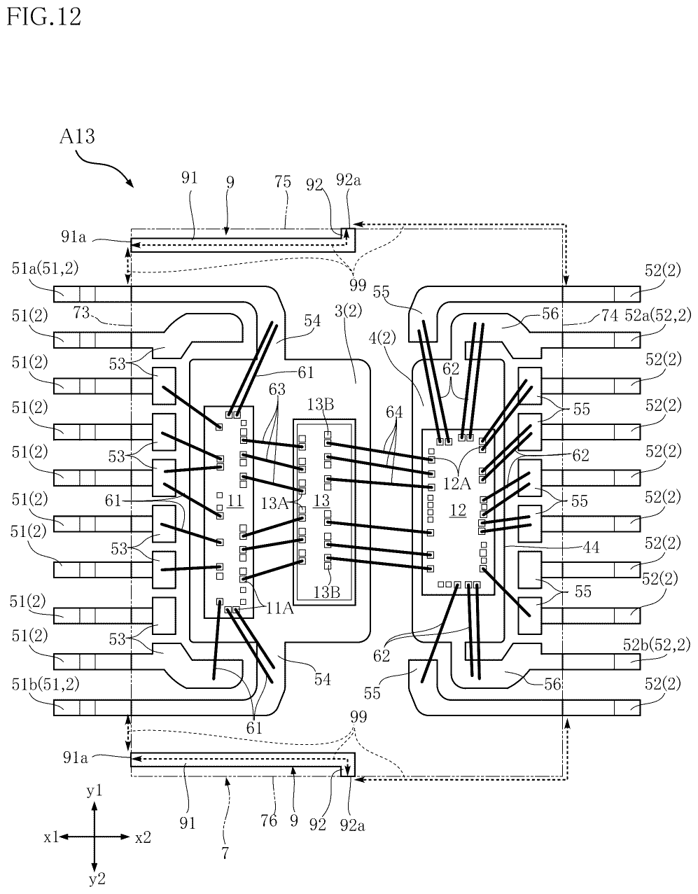

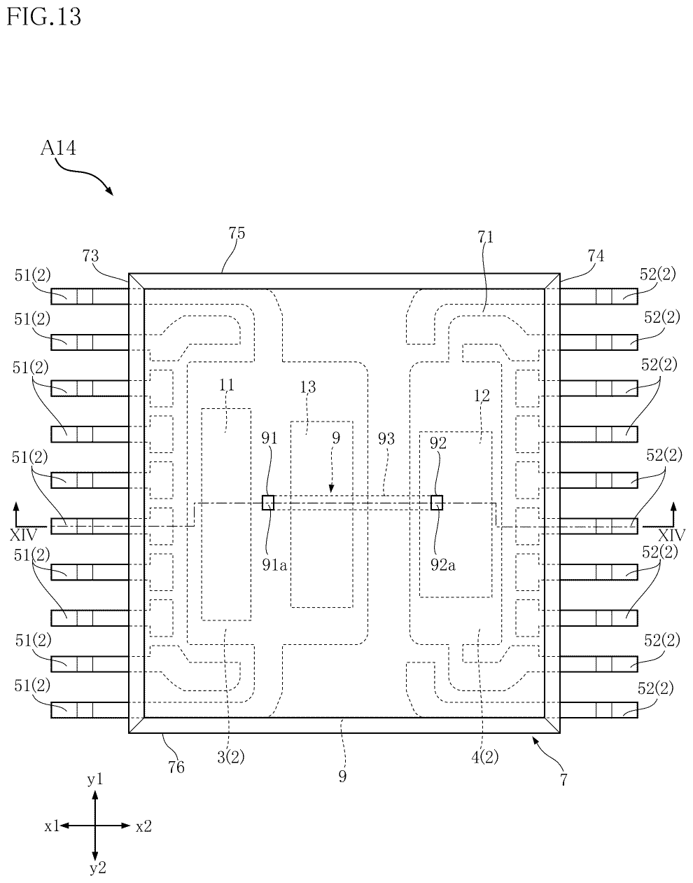

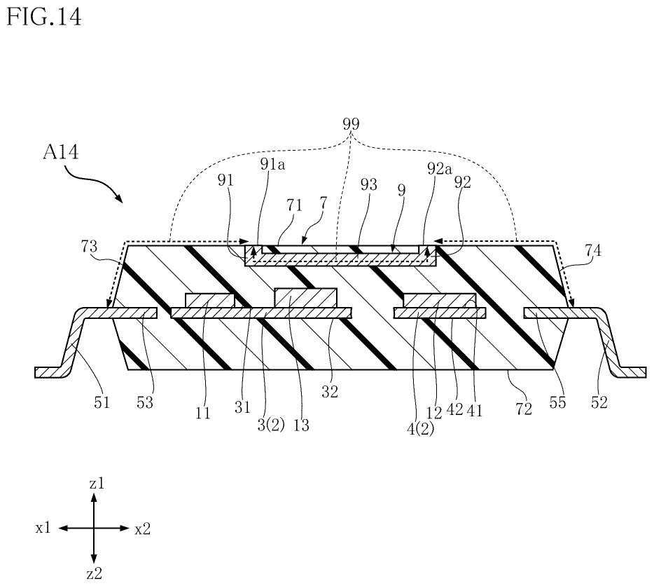

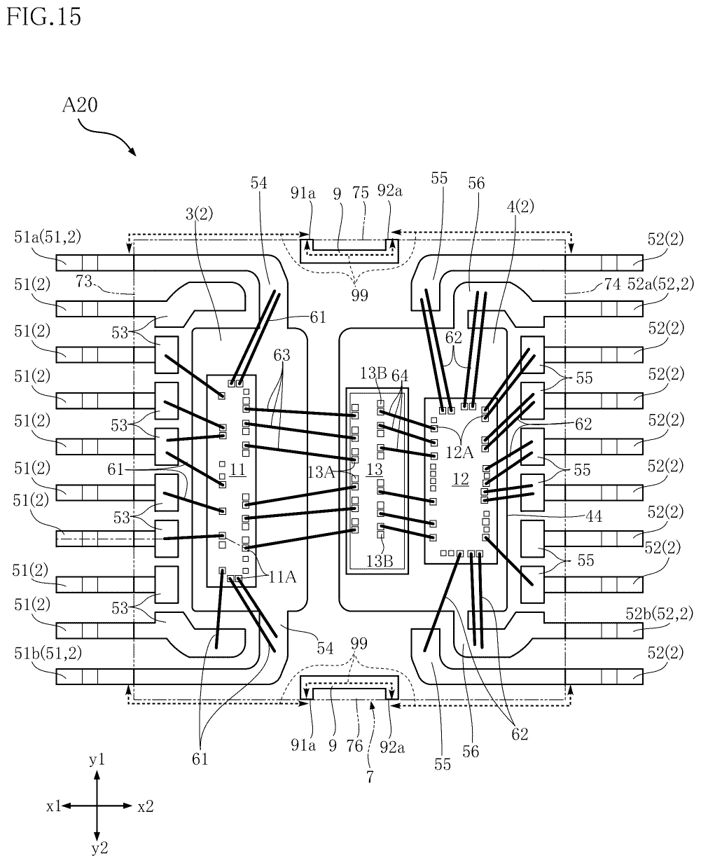

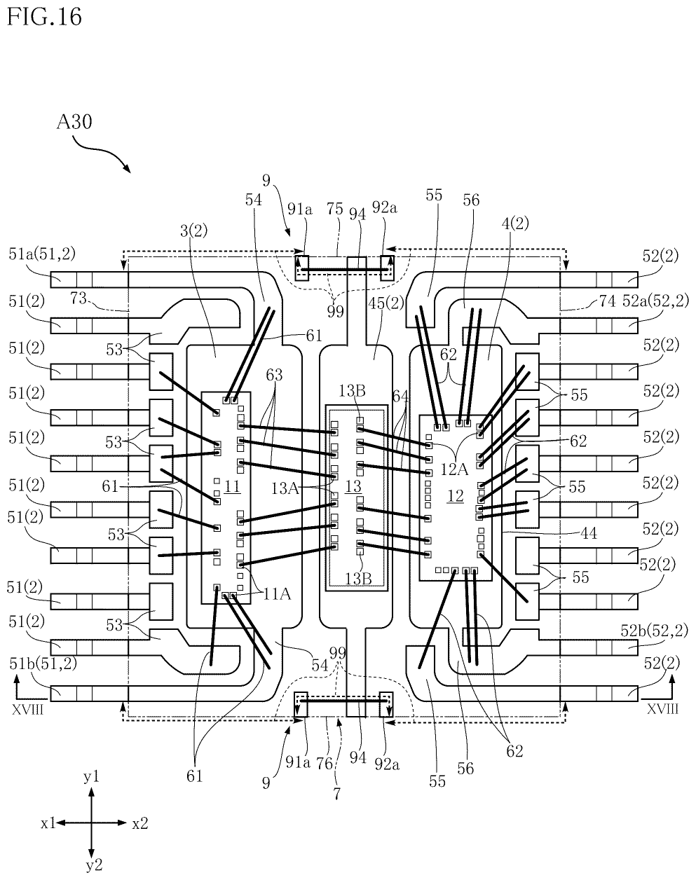

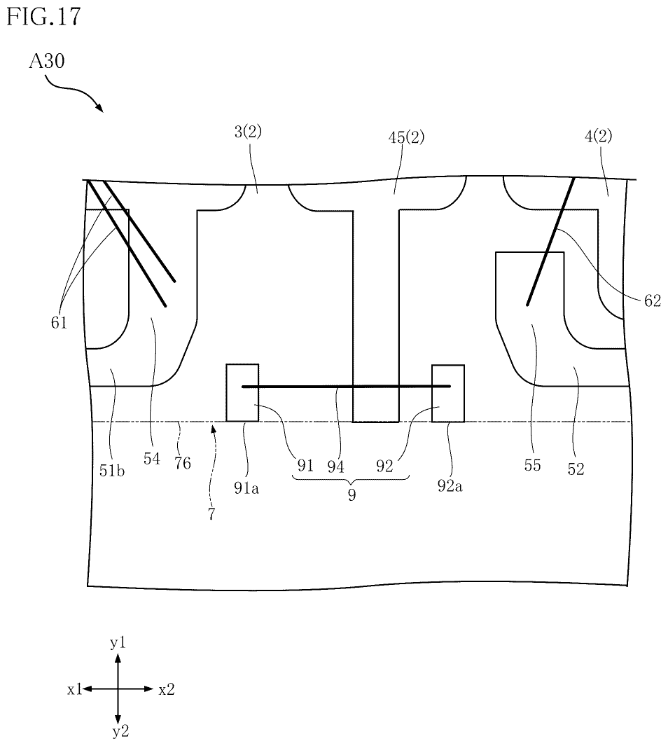

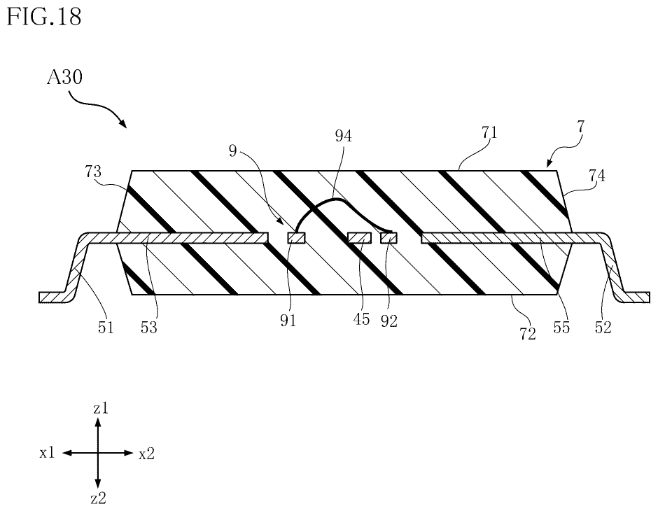

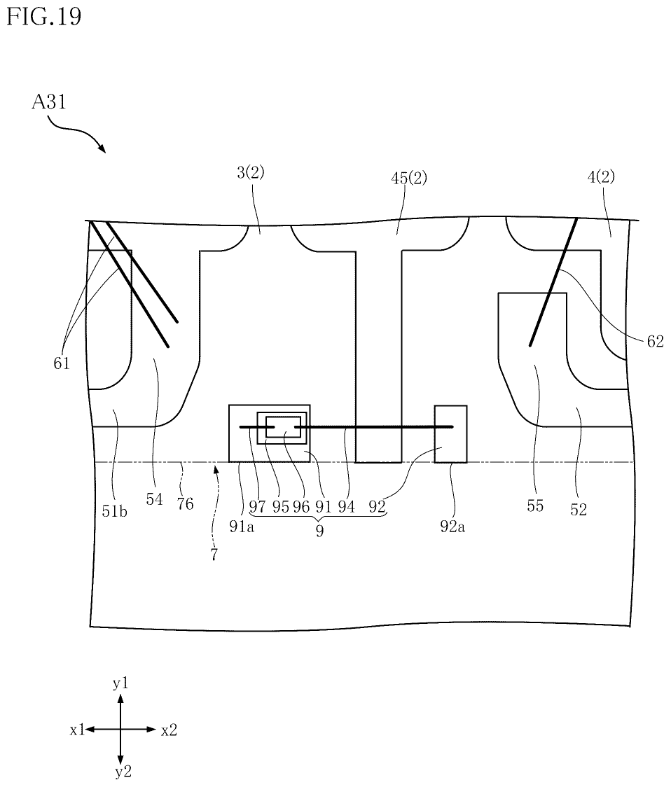

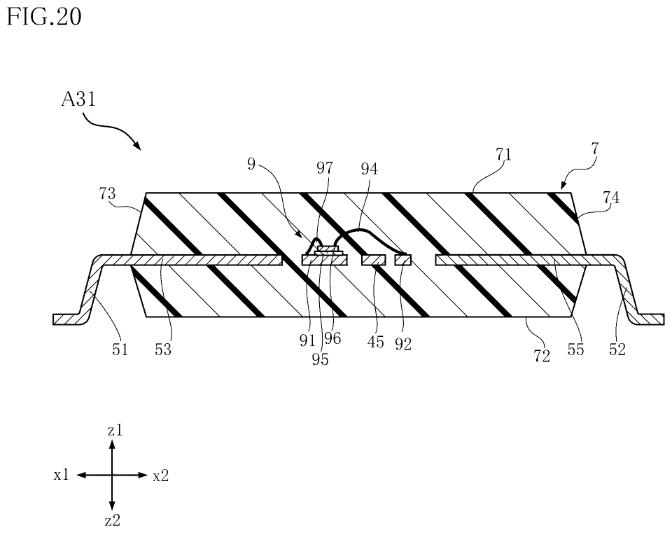

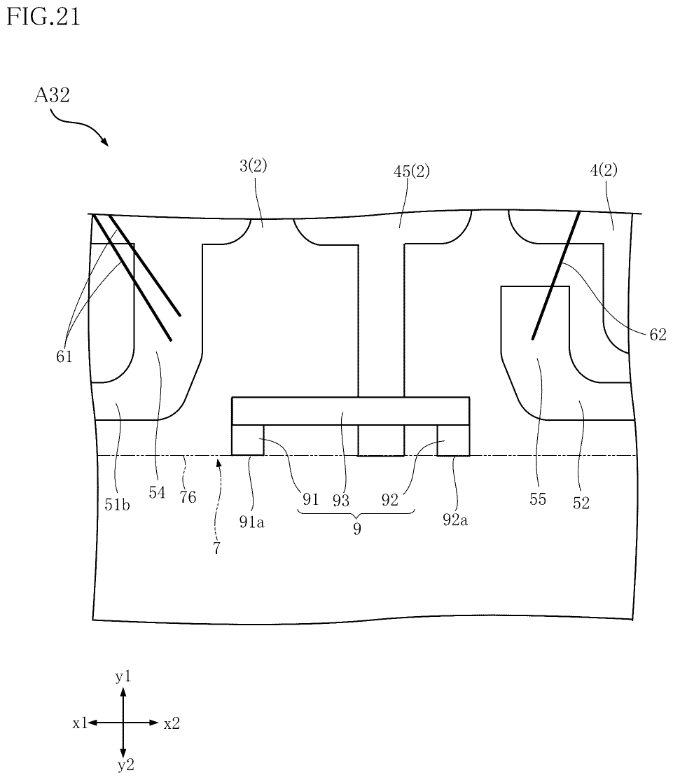

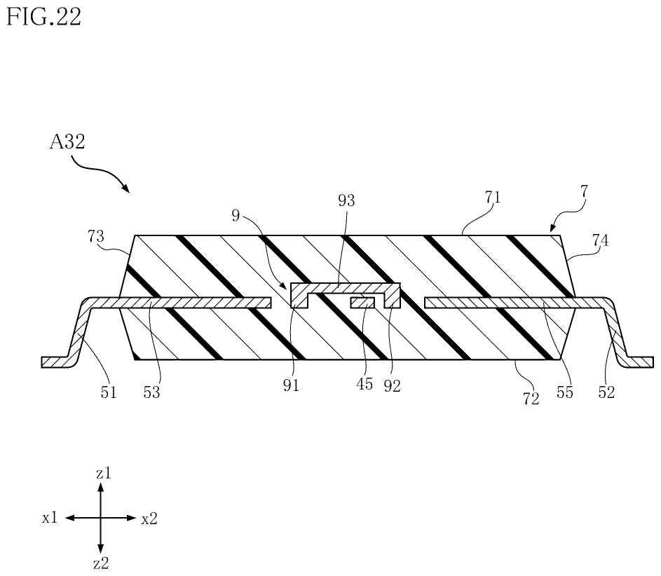

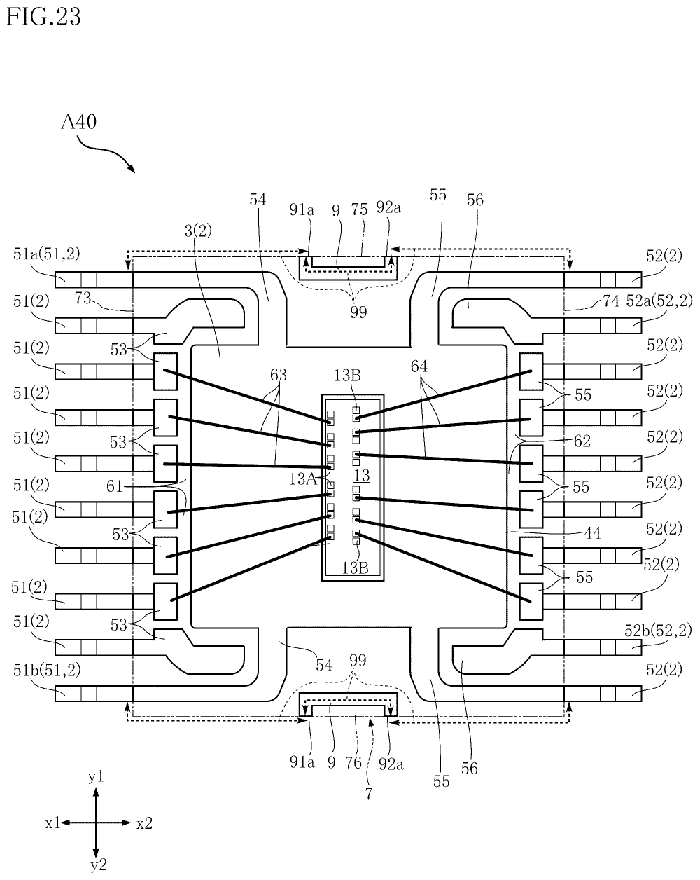

FIG. 4 is a left-side view showing the semiconductor device A10. FIG. 5 is a partially enlarged view of FIG. 2. FIG. 6 is a cross-sectional view along line VI-VI in FIG. 2. FIG. 7 is a cross-sectional view along line VII-VII in FIG. 2.

The semiconductor device A10 has a rectangular shape as viewed in the thickness direction (plan view). For the convenience of description, the thickness direction of the semiconductor device A10 is defined as a z direction, a direction along one side of the semiconductor device A10 that is perpendicular to the z direction is defined as an x direction (the horizontal direction in FIGS. 1 and 2), and the direction perpendicular to the z direction and the x direction is defined as a y direction (the vertical direction in FIGS. 1 and 2). The z direction is an example of the “thickness direction”, the x direction is an example of a “first direction”, and the y direction is an example of a “second direction”. The shape and dimensions of the semiconductor device A10 are not specifically limited.

The first semiconductor element 11, the second semiconductor element 12, and the insulating element 13 form the functional core of the semiconductor device A10.

As shown in FIG. 2, the first semiconductor element 11 is mounted on a portion (the first die pad 3 described below) of the conductive member 2, and is arranged at the center of the semiconductor device A10 in the y direction and offset to an x1 side in the x direction. The first semiconductor element 11 has a rectangular shape elongated in the y direction as viewed in the z direction. The first semiconductor element 11 is a control element. The first semiconductor element 11 has a circuit that converts a control signal inputted from, for example, an ECU into a PWM control signal, a transmission circuit that transmits the PWM control signal to the second semiconductor element 12, and a reception circuit that receives an electric signal from the second semiconductor element 12.

As shown in FIG. 2, the second semiconductor element 12 is mounted on a portion (the second die pad 4 described below) of the conductive member 2, and is arranged at the center of the semiconductor device A10 in the y direction and offset to an x2 side in the x direction. The second semiconductor element 12 has a rectangular shape elongated in the y direction as viewed in the z direction. The second semiconductor element 12 is a drive element. The second semiconductor element 12 has a reception circuit that receives a PWM control signal from the first semiconductor element 11, a circuit (gate driver) that generates and outputs a drive signal for a switching element (e.g., IGBT or MOSFET) based on the PWM control signal, and a transmission circuit that transmits an electric signal to the first semiconductor element 11.

As shown in FIG. 2, the insulating element 13 is mounted on a portion (the first die pad 3) of the conductive member 2, and is arranged at the center of the semiconductor device A10 in the y direction. The insulating element 13 is located on the x2 side in the x direction relative to the first semiconductor element 11 and on the x1 side in the x direction relative to the second semiconductor element 12. In other words, the insulating element 13 is located between the first semiconductor element 11 and the second semiconductor element 12 in the x direction. The insulating element 13 has a rectangular shape elongated in the y direction as viewed in the z direction. The insulating element 13 transmits electric signals, including a PWM control signal, without an electrical connection. The insulating element 13 receives a PWM control signal from the first semiconductor element 11 via the wires 63, and transmits the PWM control signal to the second semiconductor element 12 via the wires 64 without an

The insulating element 13 receives an electrical connection. electric signal from the second semiconductor element 12 via the wires 64, and transmits the electric signal to the first semiconductor element 11 via the wires 63 without an electrical connection. In other words, the insulating element 13 relays a signal between the first semiconductor element 11 and the second semiconductor element 12, and insulates the first semiconductor element 11 and the second semiconductor element 12 from each other.

In the present embodiment, the insulating element 13 is an inductive insulating element. The inductive insulating element transmits an electric signal without an electrical connection by inductively coupling two inductors (coils). The insulating element 13 has a Si substrate on which an inductor made of Cu is formed. The inductors include a transmission inductor and a reception inductor, which are stacked in the thickness direction (z direction) of the insulating element 13. A dielectric layer made of, for example, SiO₂ is provided between the transmission inductor and the reception inductor. The dielectric layer electrically insulates the transmission inductor from the reception inductor. Although the insulating element 13 is of an inductive type in the present embodiment, the insulating element 13 may be of a capacitive type. An example of the capacitive insulating element 13 is a capacitor.

The first semiconductor element 11 transmits a PWM control signal to the second semiconductor element 12 via the insulating element 13. Note that the first semiconductor element 11 may transmit a signal other than the PWM control signal to the second semiconductor element 12. The second semiconductor element 12 transmits an electric signal to the first semiconductor element 11 via the insulating element 13. The information indicated by the electric signal transmitted from the second semiconductor element 12 to the first semiconductor element 11 is not particularly limited.

In general, a motor driver circuit used in an inverter of a hybrid vehicle, for example, is a half-bridge circuit composed of a low-side switching element and a high-side switching element connected in a totem-pole configuration. An insulated gate driver turns on only one of the low-side switching element and the high-side switching element at any given time. In a high-voltage region, the source of the low-side switching element and the reference potential of the insulated gate driver for driving the low-side switching element are connected to a ground, so that the setting of the gate-to-source voltage is relative to the ground. On the other hand, the source of the high-side switching element and the reference potential of the insulated gate driver for driving the high-side switching element are connected to the output node of the half-bridge circuit. The potential at the output node of the half-bridge circuit changes depending on which of the low-side switching element and the high-side switching element is on, so that the reference potential of the high-side insulated gate driver changes as well. When the high-side switching element is on, the reference potential is equal to the voltage applied to the drain of the high-side switching element (e.g., 600 V or higher). The first semiconductor element 11 and the second semiconductor element 12 are connected to different grounds to ensure insulation. When the semiconductor device A10 is used as the insulated gate driver for driving the high-side switching element, the second semiconductor element 12 is subjected to a transient voltage of 600 V or higher relative to the ground of the first semiconductor element 11. In light of such a large potential difference between the first semiconductor element 11 and the second semiconductor element 12, the semiconductor device A10 includes the insulating element 13 that electrically insulates an input-side circuit including the first semiconductor element 11 and an output-side circuit including the second semiconductor element 12 from each other. In other words, the insulating element 13 provides electrical insulation between the input-side circuit held at lower potential and the output-side circuit held at higher potential.

The insulating element 13 may break down if a voltage not less than a dielectric withstand voltage V1 is applied thereto. Thus, the semiconductor device A10 is used in such a manner that the maximum value (working voltage) V2 of the potential difference between the input-side circuit and the output-side circuit is lower than the dielectric withstand voltage V1. For example, the dielectric withstand voltage V1 is approximately 3000 V, and the working voltage V2 is approximately 1000 V. V1 and V2 are not particularly limited.

As shown in FIG. 2, a plurality of electrodes 11A are provided on the upper surface (the surface facing the z1 side) of the first semiconductor element 11. The electrodes 11A are electrically connected to the circuit configured in the first semiconductor element 11. Similarly, a plurality of electrodes 12A are provided on the upper surface (the surface facing the z1 side) of the second semiconductor element 12. The electrodes 12A are electrically connected to the circuit configured in the second semiconductor element 12. A plurality of first electrodes 13A and a plurality of second electrodes 13B are provided on the upper surface (the surface facing the z1 side) of the insulating element 13. Each of the first electrodes 13A and the second electrodes 13B is electrically connected to either the transmission inductor or the reception inductor. In the insulating element 13, the first electrodes 13A are offset to the x1 side in the x direction and arranged in the y direction. The second electrodes 13B are provided near the middle in the x direction and arranged in the y direction.

The conductive member 2 of the semiconductor device A10 forms a conductive path connecting each of the first semiconductor element 11 and the second semiconductor element 12 to the wiring board of an inverter. The conductive member 2 may be made of an alloy containing Cu. The conductive member 2 is formed from a lead frame 81, which is described below. The conductive member 2 has the first semiconductor element 11, the second semiconductor element 12, and the insulating element 13 mounted thereon. As shown in FIG. 2, the conductive member 2 includes the first die pad 3, the second die pad 4, the first terminals 51, the second terminals 52, the pad portions 53 and 55, the pair of connecting portions 54, and the pair of connecting portions 56.

In the semiconductor device A10, the first die pad 3 is arranged at the center in the y direction and offset to the x1 side in the x direction. The second die pad 4 is offset to the x2 side in the x direction relative to the first die pad 3, and is spaced apart from the first die pad 3.

As shown in FIGS. 2 and 6, the first die pad 3 has the first semiconductor element 11 and the insulating element 13 mounted thereon. The first die pad 3 is electrically connected to the first semiconductor element 11, and is an element of the input-side circuit described above. The first die pad 3 has a rectangular shape (or a substantially rectangular shape) as viewed in the z direction, for example. The first die pad 3 has a first obverse surface 31 and a first reverse surface 32. As shown in FIGS. 6 and 7, the first obverse surface 31 and the first reverse surface 32 are spaced apart from each other in the z direction. The first obverse surface 31 faces the z1 side, and the first reverse surface 32 faces a z2 side. Each of the first obverse surface 31 and the first reverse surface 32 is flat (or substantially flat). The first semiconductor element 11 and the insulating element 13 are bonded to the first obverse surface 31 of the first die pad 3 via non-illustrated conductive bonding material (such as solder, metal paste, or sintered metal).

As shown in FIGS. 2 and 6, the second die pad 4 has the second semiconductor element 12 mounted thereon. The second die pad is connected 4 electrically to the second semiconductor element 12, and is an element of the output-side circuit described above. The second die pad 4 has a rectangular shape (or a substantially rectangular shape) as viewed in the z direction, for example. The second die pad 4 has a second obverse surface 41 and a second reverse surface 42. As shown in FIG. 6, the second obverse surface 41 and the second reverse surface 42 are spaced apart from each other in the z direction. The second obverse surface 41 faces the z1 side, and the second reverse surface 42 faces the z2 side. Each of the second obverse surface 41 and the second reverse surface 42 is flat (or substantially flat). The second semiconductor element 12 is bonded to the second obverse surface 41 of the second die pad 4 via non-illustrated conductive bonding material (such as solder, metal paste, or sintered metal).

When bonded to the wiring board of an inverter, the first terminals 51 provide conduction paths between the semiconductor device A10 and the wiring board. Each first terminal 51 is an element of the input-side circuit described connected to the first above, and is electrically semiconductor element 11 as appropriate. As shown in FIGS. 1, 2, and 4, the first terminals 51 are spaced apart from each other, and are arranged in the y direction at equal intervals. The first terminals 51 are located on the x1 side in the x direction relative to the first die pad 3, and protrude from the sealing resin 7 (a first side surface 73 described below) to the x1 side in the x direction. The first terminals 51 include a power supply terminal for receiving supply voltage, a ground terminal, an input terminal for receiving a control signal, an input terminal for receiving another electric signal, and an output terminal for outputting another electric signal. In the present embodiment, the semiconductor device A10 includes ten first terminals 51. The number of first terminals 51 is not particularly limited. The signals inputted or outputted through the first terminals 51 are not particularly limited.

Each first terminal 51 has a rectangular shape elongated in the x direction, and includes a portion exposed from the sealing resin 7 and a portion covered with the sealing resin 7. As shown in FIGS. 3 and 6, the portion of each first terminal 51 exposed from the sealing resin 7 is bent into a gull-wing shape. The portion of each first terminal 51 that is exposed from the sealing resin 7 may be plated. The plating layer formed by the plating may be made of an alloy containing Sn, such as solder, and covers the portion exposed from the sealing resin 7. When the semiconductor device A10 is surface-mounted to the wiring board of an inverter by soldering, the plating layer facilitates adhesion of solder to the exposed portion and also prevents corrosion of the exposed portion caused by soldering. The first terminals 51 include a first terminal 51a and a first terminal 51b. Of the first terminals 51, the first terminal 51a is arranged farthest on a y1 side in the y direction. Of the first terminals 51, the first terminal 51b is arranged farthest on a y2 side in the y direction.

The pad portions 53 are connected to the respective ends of the first terminals 51 other than the first terminals 51a and 51b on the x2 side in the x direction. The shape of each pad portion 53 as viewed in the z direction is not particularly limited. The upper surface (the surface facing the z1 side) of each pad portion 53 is flat (or substantially flat), and has a wire 61 (described below) bonded thereto. The upper surface of each pad portion 53 may be plated. The plating layer formed by the plating may be made of a metal including Ag for example, and covers the upper surface of each pad portion 53. The plating layer increases the bonding strength of the wires 61, and protects the lead frame 81 (described below) from a shock during the bonding of the wires 61. Each pad portion 53 is entirely covered with the sealing resin 7.

Each of the pair of connecting portions 54 is connected to either the first terminal 51a or the first terminal 51b and to the first die pad 3. The connecting portion 54 connected to the first terminal 51a extends in the y direction, and the end of the connecting portion 54 on the y2 side in the y direction is connected to the end of the first die pad 3 on the y1 side in the y direction at a position near the middle in the x direction. The connecting portion 54 connected to the first terminal 51b extends in the y direction, and the end of the connecting portion 54 on the y1 side in the y direction is connected to the end of the first die pad 3 on the y2 side in the y direction at a position near the middle in the x direction. In this way, the first terminal 51a and the first terminal 51b are connected to the first die pad 3 via the pair of connecting portions 54, and support the first die pad 3. The upper surface (the surface facing the z1 side) of each connecting portion 54 is flat (or substantially flat), and has a wire 61 (described below) bonded thereto. As with the upper surface of each pad portion 53, the upper surface of each connecting portion 54 may be covered with a plating layer (a metal including Ag, for example). Each connecting portion 54 is entirely covered with the sealing resin 7.

As with the first terminals 51, when bonded to the wiring inverter, the second terminals 52 provide board of an conduction paths between the semiconductor device A10 and the wiring board. Each of the second terminals 52 is an element of the output-side circuit described above, and is electrically connected to the second semiconductor element 12 appropriate. As shown in FIGS. 1 and 2, the second terminals 52 are spaced apart from each other, and are arranged in the y direction at equal intervals. The second terminals 52 are located on the x2 side in the x direction relative to the second die pad 4, and protrude from the sealing resin 7 (a second side surface 74 described below) to the x2 side in the x direction. The second terminals 52 include a power supply terminal for receiving supply voltage, a ground terminal, an output terminal for outputting a drive signal, an input terminal for receiving another electric signal, and an output terminal for outputting another electric signal. In the present embodiment, the semiconductor device A10 includes ten second terminals 52. The number of second terminals 52 is not particularly limited. The signals inputted or outputted through the second terminals 52 are not particularly limited.

Each second terminal 52 has a rectangular shape elongated in the x direction, and includes a portion exposed from the sealing resin 7 and a portion covered with the sealing resin 7. As shown in FIGS. 3 and 6, the portion of each second terminal 52 exposed from the sealing resin 7 is bent into a gull-wing shape. As with the first semiconductor element 11, a plating layer (e.g., an alloy containing Sn, such as solder) may be formed on the portion of each second terminal 52 that is exposed from the sealing resin 7. The second terminals 52 include a second terminal 52a and a second terminal 52b. Of the second terminals 52, the second terminal 52a is arranged second from the y1 side in the y direction. Of the second terminals 52, the second terminal 52b is arranged second from the y2 side in the y direction.

The pad portions 55 are connected to the respective ends of the second terminals 52 other than the second terminals 52a and 52b on the x1 side in the x direction. The shape of each pad portion 55 as viewed in the z direction is not particularly limited. The upper surface (the surface facing the z1 side) of each pad portion 55 is flat (or substantially flat), and has a wire 62 (described below) bonded thereto. As with the upper surface of each pad portion 53, the upper surface of each pad portion 55 may be covered with a plating layer (e.g., a metal such as Ag). Each pad portion 55 is entirely covered with the sealing resin 7.

Each of the pair of connecting portions 56 is connected to either the second terminal 52a or the second terminal 52b and to the second die pad 4. The connecting portion 56 connected to the second terminal 52a has an end on the y2 side in the y direction, and the end is connected to the end of the second die pad 4 on the yl side in the y direction at a position near the middle in the x direction. The connecting portion 56 connected to the second terminal 52b has an end on the yl side in the y direction, and the end is connected to the end of the second die pad 4 on the y2 side in the y direction at a position near the middle in the x direction. In this way, the second terminal 52a and the second terminal 52b are connected to the second die pad 4 via the pair of connecting portions 56, and support the second die pad 4. The upper surface e (the surface facing the z1 side) of each connecting portion 56 is flat (or substantially flat), and has a wire 62 (described below) bonded thereto. As with the upper surface of each pad portion 53, the upper surface of each connecting portion 56 may be covered with a plating layer (e.g., a metal such as Ag). Each connecting portion 56 is entirely covered with the sealing resin 7.

The shape of the conductive member 2 is not limited to the above. For example, the first die pad 3 may be supported by any of the first terminals 51. In other words, the pair of connecting portions 54 may be connected to the first die pad 3 and any two of the first terminals 51. Further, the second die pad 4 may be supported by any of the second terminals 52. In other words, the pair of connecting portions 56 may be connected to the second die pad 4 and any two of the second terminals 52.

The pair of discharge portions 9 are provided to generate creeping discharge on purpose. Since the working voltage V2 of the semiconductor device A10 is smaller than the dielectric withstand voltage V1, a voltage higher than or equal to the dielectric withstand voltage V1 is not normally applied to the insulating element 13. However, an overvoltage higher than the dielectric withstand voltage V1 may be applied abruptly across the input-side circuit and the output-side circuit. The semiconductor device A10 includes discharge paths 99, each of which is a conductive path that energizes the input-side circuit and the output-side circuit when the potential difference between the input-side circuit and the output-side circuit reaches a creeping discharge voltage V3 or higher. The creeping discharge voltage V3 is higher than the working voltage V2 and lower than the dielectric withstand voltage V1. When the dielectric withstand voltage V1 is approximately 3000 V and the working voltage V2 is approximately 1000 V, the creeping discharge voltage V3 may be set to approximately 2000 V. As shown by the dashed arrows in FIG. 2, each of the discharge paths 99 includes a discharge portion 9, a path formed by the creeping discharge at the surface of the sealing resin 7 between a first terminal 51 of the input-side circuit and the discharge portion 9 (an exposed surface 91a described below), and a path formed by the creeping discharge at the surface of the sealing resin 7 between a second terminal 52 of the output-side circuit and the discharge portion 9 (an exposed surface 92a described below). Each of the discharge paths 99 is a conductive path electrically conductive at the creeping discharge voltage V3 that is higher than the working voltage V2 and lower than the dielectric withstand voltage V1.

In the present embodiment, each discharge portion 9 is made of an alloy containing Cu, for example, and is formed from the lead frame 81 described below, together with the conductive member 2. As shown in FIGS. 2 and 7, one of the discharge portions 9 is arranged at the end of the semiconductor device A10 on the y1 side in the y direction at a position near the middle in both the x direction and the z direction, and a portion of the discharge portion 9 is exposed from the sealing resin 7. The other discharge portion 9 is arranged at the end of the semiconductor device A10 on the y2 side in the y direction at a position near the middle in both the x direction and the z direction, and a portion of the discharge portion 9 is exposed from the sealing resin 7. Each discharge portion 9 is spaced apart from the conductive member 2, and the sealing resin 7 is provided between the discharge portion 9 and the conductive member 2. In other words, each discharge portion 9 is insulated from the conductive member 2.

As shown in FIG. 5, each discharge portion 9 is a single member and has a U-shape as viewed in the z direction. Each discharge portion 9 includes a first portion 91, a second portion 92, and a third portion 93. The first portion 91 extends in the y direction, and has a rectangular shape as viewed in the z direction. The first portion 91 has an exposed surface 91a. The exposed surface 91a faces outward in the y direction (the y2 side in the y direction in FIG. 5), and is exposed from the sealing resin 7. The first portion 91 is covered with the sealing resin 7 except for the exposed surface 91a. The second portion 92 extends in the y direction, and has a rectangular shape as viewed in the z direction. The second portion 92 has an exposed surface 92a. The exposed surface 92a faces outward in the y direction (the y2 side in the y direction in FIG. 5), and is exposed from the sealing resin 7. The second portion 92 is covered with the sealing resin 7 except for the exposed surface 92a. The third portion 93 extends in the x direction, and has a rectangular shape as viewed in the z direction. The third portion 93 has an end connected to the first portion 91 on the x1 side in the x direction, and an end connected to the second portion 92 on the x2 side in the x direction. The third portion 93 is entirely covered with the sealing resin 7. The first portion 91 and the second portion 92 are electrically connected to each other via the third portion 93.

As the length (the dimension in the x direction) of the third portion 93 of a discharge portion 9 is increased to thereby arrange the exposed surface 91a farther on the x1 side in the x direction and arrange the exposed surface 92a farther on the x2 side in the x direction, the creeping distance is shortened. This makes it possible to lower the creeping discharge voltage V3. Each discharge portion 9 is designed to adjust the creeping discharge voltage V3 according to the dielectric withstand voltage V1 and the working voltage V2.

As shown in FIG. 2, the wires 61 to 64, together with the conductive member 2, form conductive paths for the first semiconductor element 11, the second semiconductor element 12, and the insulating element 13 to perform predetermined functions. The material of each of the wires 61 to 64 is a metal such as Au, Cu, or Al, for example.

As shown in FIGS. 2 and 6, each of the wires 61 forms a conductive path between the first semiconductor element 11 and a first terminal 51. The wires 61 electrically connect the first semiconductor element 11 to at least one of the first terminals 51. The wires 61 are elements of the input-side circuit described above. As shown in FIG. 2, each of the wires 61 has one end electrically bonded to one of the electrodes 11A of the first semiconductor element 11, and the other end connected to one of the pad portions 53 and the pair of connecting portions 54. The number of wires 61 bonded to the pad portions 53 and the connecting portions 54 is not particularly limited.

As shown in FIGS. 2 and 6, each of the wires 62 forms a conductive path between the second semiconductor element 12 and a second terminal 52. The wires 62 electrically connect the second semiconductor element 12 to at least one of the second terminals 52. The wires 62 are elements of the output-side circuit described above. As shown in FIG. 2, each of the wires 62 has one end electrically bonded to one of the electrodes 12A of the second semiconductor element 12, and the other end connected to one of the pad portions 55 and the pair of connecting portions 56. The number of wires 62 bonded to the pad portions 55 and the connecting portions 56 is not particularly limited.

As shown in FIGS. 2 and 6, each of the wires 63 forms a conductive path between the first semiconductor element 11 and the insulating element 13. The wires 63 electrically connect the first semiconductor element 11 and the insulating element 13 to each other. The wires 63 are elements of the input-side circuit described above. As shown in FIG. 2, each of the wires 63 is electrically e bonded to one of the electrodes 11A of the first semiconductor element 11 and one of the first electrodes 13A of the insulating element 13.

As shown in FIGS. 2 and 6, each of the wires 64 forms a conductive path between the second semiconductor element 12 and the insulating element 13. The wires 64 electrically connect the second semiconductor element 12 and the insulating element 13 to each other. The wires 64 are elements of the output-side circuit described above. As shown in FIG. 2, each of the wires 64 is electrically bonded to one of the electrodes 12A of the second semiconductor element 12 and one of the second electrodes 13B of the insulating element 13.

As shown in FIG. 1, the sealing resin 7 covers the first semiconductor element 11, the second semiconductor element 12, the insulating element 13, the first die pad 3, the second die pad 4, the pair of connecting portions 54, the pair of connecting portions 56, the pad portions 53 and 55, the wires 61 to 64, a portion of each first terminal 51, and a portion of each second terminal 52. The sealing resin 7 is electrically insulative. The sealing resin 7 is made of a material containing a black epoxy resin, for example. The sealing resin 7 has a rectangular shape as viewed in the z direction.

As shown in FIGS. 3 and 4, the sealing resin 7 has a top surface 71, a bottom surface 72, a first side surface 73, a second side surface 74, a third side surface 75, and a fourth side surface 76.

The top surface 71 and the bottom surface 72 are spaced apart from each other in the z direction. The top surface 71 and the bottom surface 72 face away from each other in the z The top surface 71 is located on the z1 side in direction. the z direction, and faces the z1 side as with the first obverse surface 31 of the first die pad 3. The bottom surface 72 is located on the z2 side in the z direction, and faces the z2 side as with the first reverse surface 32 of the first die pad 3. The top surface 71 and the bottom surface 72 are flat (or substantially flat).

Each of the first side surface 73, the second side surface 74, the third side surface 75, and the fourth side surface 76 is connected to the top surface 71 and the bottom surface 72, and located between the top surface 71 and the bottom surface 72 in the z direction. The first side surface 73 and the second side surface 74 are spaced apart from each other in the x direction. The first side surface 73 and the second side surface 74 face away from each other in the x direction. The first side surface 73 is located on the x1 side in the x direction, and the second side surface 74 is located on the x2 side in the x direction. The third side surface 75 and the fourth side surface 76 are spaced apart from each other in the y direction, and are connected to the first side surface 73 and the second side surface 74. The third side surface 75 and the fourth side surface 76 face away from each other in the y direction. The third side surface 75 is located on the y1 side in the y direction, and the fourth side surface 76 is located on the y2 side in the y direction.

As shown in FIG. 1, a portion of each of the first terminals 51 protrudes from the first side surface 73. A portion of each of the second terminals 52 protrudes from the second side surface 74. As shown in FIGS. 2 and 3, the exposed surfaces 91a and 92a of each discharge portion 9 are exposed from one of the third side surface 75 and the fourth side surface 76. For convenience of understanding, the exposed surfaces 91a and 92a are hatched in FIG. 3.

As shown in FIGS. 3 and 4, the first side surface 73 includes a first area 731, a second area 732, and a third area 733. The first area 731 has one end in the z direction connected to the top surface 71, and the other end in the z direction connected to the third area 733. The first area 731 is inclined to the top surface 71 and a yz plane. The second area 732 has one end in the z direction connected to the bottom surface 72, and the other end in the z direction connected to the third area 733. The second area 732 is inclined to the bottom surface 72 and the yz plane. The third area 733 has one end in the z direction connected to the first area 731, and the other end in the z direction connected to the second area 732. The third area 733 is provided along the yz plane. As viewed in the z direction, the third area 733 is located outside the top surface 71 and the bottom surface 72. A portion of each of the first terminals 51 is exposed from the third area 733.

As shown in FIG. 3, the second side surface 74 includes a fourth area 741, a fifth area 742, and a sixth area 743. The fourth area 741 has one end in the z direction connected to the top surface 71, and the other end in the z direction connected to the sixth area 743. The fourth area 741 is inclined to the top surface 71 and the yz plane. The fifth area 742 has one end in the z direction connected to the bottom surface 72, and the other end in the z direction connected to the sixth area 743. The fifth area 742 is inclined to the bottom surface 72 and the yz plane. The sixth area 743 has one end in the z direction connected to the fourth area 741, and the other end in the z direction connected to the fifth area 742. The sixth area 743 is provided along the yz plane. As viewed in the z direction, the sixth area 743 is located outside the top surface 71 and the bottom surface 72. A portion of each of the second terminals 52 is exposed from the sixth area 743.

As shown in FIG. 4, the third side surface 75 includes a seventh area 751, an eighth area 752, and a ninth area 753. The seventh area 751 has one end in the z direction connected to the top surface 71, and the other end in the z direction connected to the ninth area 753. The seventh area 751 is inclined to the top surface 71 and an xz plane. The eighth area 752 has one end in the z direction connected to the bottom surface 72, and the other end in the z direction connected to the ninth area 753. The eighth area 752 is inclined to the bottom surface 72 and the xz plane. The ninth area 753 has one end in the z direction connected to the seventh area 751, and the other end in the z direction connected to the eighth area 752. The ninth area 753 is provided along the xz plane. As viewed in the z direction, the ninth area 753 is located outside the top surface 71 and the bottom surface 72.

As shown in FIGS. 3 and 4, the fourth side surface 76 includes a tenth area 761, an eleventh area 762, and a twelfth area 763. The tenth area 761 has one end in the z direction connected to the top surface 71, and the other end in the z direction connected to the twelfth area 763. The tenth area 761 is inclined to the top surface 71 and the xz plane. The eleventh area 762 has one end in the z direction connected to the bottom surface 72, and the other end in the z direction connected to the twelfth area 763. The eleventh area 762 is inclined to the bottom surface 72 and the xz plane. The twelfth area 763 has one end in the z direction connected to the tenth area 761, and the other end in the z direction connected to the eleventh area 762. The twelfth area 763 is provided along the xz plane. As viewed in the z direction, the twelfth area 763 is located outside the top surface 71 and the bottom surface 72.

As shown in FIG. 3, the exposed surface 91a of the first portion 91 of a discharge portion 9 and the exposed surface 92a of the second portion 92 of the discharge portion 9 are exposed from the twelfth area 763. Although not illustrated, the exposed surface 91a of the first portion 91 of another discharge portion 9 and the exposed surface 92a of the second portion 92 of the discharge portion 9 are exposed from the ninth area 753.

Next, an example of a method for manufacturing the semiconductor device A10 will be described below with reference to FIGS. 8 and 9. FIGS. 8 and 9 are plan views each showing a step of manufacturing the semiconductor device A10.

First, a lead frame 81 is prepared as shown in FIG. 8. The lead frame 81 is a plate-like material. In the present embodiment, the base material of the lead frame 81 is Cu. The lead frame 81 may be formed by etching or punching a metal plate, for example. In the present embodiment, the lead frame 81 is formed by etching. The lead frame 81 has an obverse surface 81A and a reverse surface 81B that are spaced apart from each other in the z direction. The lead frame 81 includes an outer frame 811, a first die pad 812A, a second die pad 812B, a plurality of first leads 813, a plurality of second leads 814, a plurality of connecting portions 815, a dam bar 816, and a discharge portion 817. Of these elements, the outer frame 811 and the dam bar 816 do not constitute the semiconductor device A10. The first die pad 812A will be formed into a first die pad 3. The second die pad 812B will be formed into a second die pad 4. The first leads 813 will be formed into a plurality of first terminals 51 and a plurality of pad portions 53. The second leads 814 will be formed into a plurality of second terminals 52 and a plurality of pad portions 55. The connecting portions 815 will be formed into a pair of connecting portions 54 and a pair of connecting portions 56. The discharge portion 817 will be formed into a discharge portion 9.

Next, as shown in FIG. 9, a first semiconductor element 11 and an insulating element 13 are bonded to the first die pad 812A by die bonding, and a second semiconductor element 12 is bonded to the second die pad 812B by die bonding. Next, a plurality of wires 61 to 64 are provided by wire bonding. Next, a sealing resin 7 is formed. The sealing resin 7 is formed by transfer molding. In this step, the lead frame 81 is placed in a mold having a plurality of cavities. At this point, portions of the lead frame 81 that will be formed into a conductive member 2 and the discharge portion 9 and that will be covered with the sealing resin 7 in the semiconductor device A10 are placed in the respective cavities. Then, fluidized resin is introduced into the cavities from a pot via a runner. The fluidized resin in each cavity is solidified to form the sealing resin 7, and the resin burrs remaining outside the cavities are removed by, for example, applying high-pressure water jet. This completes the formation of the sealing resin 7.

Next, dicing is performed to isolate individual pieces, whereby the first leads 813 and the second leads 814 connected by the outer frame 811 and the dam bar 816 are separated as appropriate. Through the steps described above, the semiconductor device A10 is manufactured.

The following describes advantages of the semiconductor device A10.

According to the present embodiment, the semiconductor device A10 includes the discharge paths 99 each including a discharge portion 9. Each of the discharge paths 99 is a conductive path electrically conductive at the creeping discharge voltage V3. Each of the discharge paths 99 electrically connects a first terminal 51 of the input-side circuit and a second terminal 52 of the output-side circuit when a voltage not less than the creeping discharge voltage V3 is applied across the input-side circuit and the output-side circuit. This prevents a voltage not less than the dielectric withstand voltage V1 which is higher than the creeping discharge voltage V3 from being applied to the insulating element 13. Thus, the semiconductor device A10 can prevent the insulating element 13 from being destroyed by the application of a voltage not less than the dielectric withstand voltage V1.

According to the present embodiment, each of the discharge portions 9 is designed such that the creeping discharge voltage V3 is adjusted by the arrangement positions of the exposed surface 91a and the exposed surface 92a exposed from the sealing resin 7. Thus, the semiconductor device A10 can set the creeping discharge voltage V3 to an appropriate voltage according to the dielectric withstand voltage V1 and the working voltage V2.

According to the present embodiment, each of the discharge portions 9 is a single member formed from a portion of the lead frame 81 for forming the conductive member 2. Accordingly, the manufacturing method of the semiconductor device A10 does not need to include a step of forming only the discharge portions 9, and the semiconductor device A10 can be manufactured through the same steps as the manufacturing steps of a semiconductor device without the discharge portions 9.

According to the present embodiment, the semiconductor device A10 includes the discharge portion 9 exposed from the third side surface 75 and the discharge portion 9 exposed from the fourth side surface 76. However, the present disclosure is not limited to this example. The semiconductor device A10 may include only one of the discharge portions 9.

FIGS. 10 to 14 show variations of the semiconductor device A10 according to the first embodiment. In these figures, elements that are the same as or similar to those in the above embodiment are provided with the same reference numerals as in the above embodiment, and descriptions thereof are omitted.

### First Variation:

FIG. 10 is a view for describing a semiconductor device A11 according to a first variation of the first embodiment. FIG. 10 is a plan view showing the semiconductor device A11, and corresponds to FIG. 2. For convenience of understanding, FIG. 10 shows the sealing resin 7 in phantom, and the outline of the sealing resin 7 is indicated by an imaginary line (two-dot chain line). The semiconductor device A11 is different from the semiconductor device A10 in the shape of each discharge portion 9. In the present variation, each of the discharge portions 9 has a rectangular shape as viewed in the z direction, and has an exposed surface 9a. The exposed surface 9a faces outward in the y direction, and is exposed from the sealing resin 7. As compared to the semiconductor device A10, the semiconductor device A11 is such that a path formed by the creeping discharge at the surface of the sealing resin 7 between a first terminal 51 and a discharge portion 9, and a path formed by the creeping discharge at the surface of the sealing resin 7 between a second terminal 52 and the discharge portion 9 are long. Thus, the semiconductor device A11 can set the creeping discharge voltage V3 to a higher voltage.

### Second Variation:

FIG. 11 is a view for describing a semiconductor device A12 according to a second variation of the first embodiment. FIG. 11 is a plan view showing the semiconductor device A12, and corresponds to FIG. 2. For convenience of understanding, FIG. 11 shows the sealing resin 7 in phantom, and the outline of the sealing resin 7 is indicated by an imaginary line (two-dot chain line). The semiconductor device A12 is different from the semiconductor device A10 in the shape of each discharge portion 9. In the present variation, each of the discharge portions 9 has a rectangular shape elongated in the x direction as viewed in the z direction, and has two ends extending to the respective ends of the sealing resin 7 in the x direction. In each of the discharge portions 9, the first portion 91 extending in the x direction and having the exposed surface 91a exposed from the first side surface 73 is directly connected to the second portion 92 extending in the x direction and having the exposed surface 92a exposed from the second side surface 74. As compared to the semiconductor device A10, the semiconductor device A12 is such that a path formed by the creeping discharge at the surface of the sealing resin 7 between a first terminal 51 and a discharge portion 9 (an exposed surface 91a), and a path formed by the creeping discharge at the surface of the sealing resin 7 between a second terminal 52 and the discharge portion 9 (an exposed surface 92a) are short. Thus, the semiconductor device A12 can set the creeping discharge voltage V3 to a lower voltage. Third variation: FIG. 12 is a view for describing a semiconductor device A13 according to a third variation of the first embodiment. FIG. 12 is a plan view showing the semiconductor device A13, and corresponds to FIG. 2. For convenience of understanding, FIG. 12 shows the sealing resin 7 in phantom, and the outline of the sealing resin 7 is indicated by an imaginary line (two-dot chain line). The semiconductor device A13 is different from the semiconductor device A10 in the shape of each discharge portion 9. In the present variation, each of the discharge portions 9 has an L-shape as viewed in the z direction. In each of the discharge portions 9, the first portion 91 extending in the x direction and having the exposed surface 91a exposed from the first side surface 73 is directly connected to the second portion 92 extending in the y direction and having the exposed surface 92a exposed from the third side surface 75 or the fourth side surface 76. Note that the exposed surface 91a may face the x2 side in the x direction, and may be exposed from the second side surface 74 of the sealing resin 7.

As can be understood from the first embodiment and the first to third variations, the shape of each discharge portion 9 is not particularly limited. The shape of each discharge portion 9 and the arrangement positions of the exposed surfaces of each discharge portion 9 are selected as appropriate according to a desirable value of the creeping discharge voltage V3.

### Fourth Variation:

FIGS. 13 and 14 are views for describing a semiconductor device A14 according to a fourth variation of the first embodiment. FIG. 13 is a plan view showing the semiconductor device A14, and corresponds to FIG. 1. FIG. 14 is a cross-sectional view along line XIV-XIV in FIG. 13. The semiconductor device A14 is different from the semiconductor device A10 in the arrangement position of a discharge portion 9. In the present variation, the discharge portion 9 is arranged near the center of the semiconductor device A14 in the x direction and the y direction and at the end on the z1 side in the z direction, and is partially exposed from the sealing resin 7. The first portion 91 extends in the z direction, and the exposed surface 91a is exposed from the top surface 71 of the sealing resin 7. The second portion 92 extends in the z direction, and the exposed surface 92a is exposed from the top surface 71 of the sealing resin 7. Note that the semiconductor device A14 may include a plurality of discharge portions 9. In another example, the discharge portion 9 may be arranged at the end of the semiconductor device A14 on the z2 side in the z direction, and the exposed surfaces 91a and 92a may be exposed from the bottom surface 72 of the sealing resin 7. In another example, the semiconductor device A14 may include a discharge portion 9 arranged at the end on the z1 side in the z direction, and a discharge portion 9 arranged at the end on the z2 side in the z direction.

As can be understood from the first embodiment and the fourth variation, the arrangement position of a discharge portion 9 and the number of discharge portions 9 are not particularly limited. The arrangement position of a discharge portion 9 and the number of discharge portions 9 may be selected as appropriate according to the shape, size, arrangement, etc., of each of the sealing resin 7, the conductive member 2, the elements 11, 12, and 13, and the wires 61 to 64.

FIGS. 15 to 21 show other embodiments of the present disclosure. In these figures, elements that are the same as or similar to those in the above embodiment are provided with the same reference numerals as in the above embodiment.

### Second Embodiment

FIG. 15 is a view for describing a semiconductor device A20 according to a second embodiment of the present disclosure. FIG. 15 is a plan view showing the semiconductor device A20, and corresponds to FIG. 2. For convenience of understanding, FIG. 15 shows the sealing resin 7 in phantom, and the outline of the sealing resin 7 is indicated by an imaginary line (two-dot chain line). The semiconductor device A20 of the present embodiment is different from the semiconductor device of the first embodiment in that the insulating element 13 is mounted on the second die pad 4. The configurations and operations of the other elements in the present embodiment are the same as those in the first embodiment. It should be understood that the second embodiment may include any of the elements described in the first embodiment and the variations described above in any combination.

In the present embodiment, the second die pad 4 has a larger dimension in the x direction than in the first embodiment. On the other hand, the first die pad 3 has a smaller dimension in the x direction than in the first embodiment. In the present embodiment, the insulating element 13 is mounted on the second die pad 4.

The semiconductor device A20 according to the present embodiment also includes the discharge paths 99 each including a discharge portion 9, thereby preventing a voltage not less than the dielectric withstand voltage V1 which is higher than the creeping discharge voltage V3 from being applied to the insulating element 13. Further, the semiconductor device A20 has a configuration in common with the semiconductor device A10, thereby achieving the same advantages as the semiconductor device A10.

### Third Embodiment

FIGS. 16 to 18 are views for describing a semiconductor device A30 according to a third embodiment of the present disclosure. FIG. 16 is a plan view showing the semiconductor device A30, and corresponds to FIG. 2. For convenience of understanding, FIG. 16 shows the sealing resin 7 in phantom, and the outline of the sealing resin 7 is indicated by an imaginary line (two-dot chain line). FIG. 17 is a partially enlarged view of FIG. 16. FIG. 18 is a cross-sectional view along line XVIII-XVIII in FIG. 16. The semiconductor device A30 of the present embodiment is different from the semiconductor device of the first embodiment in further including a third die pad 45 on which the insulating element 13 is mounted, and in the configuration of each discharge portion 9. The configurations and operations of the other elements in the present embodiment are the same as those in the first embodiment. It should be understood that the third embodiment may include any of the elements described in the first and second embodiments and the variations described above in any combination.

According to the present embodiment, the conductive member 2 further includes a third die pad 45. The third die pad 45 is disposed between the first die pad 3 and the second die pad 4 in the x direction, and is spaced apart from the first die pad 3 and the second die pad 4. The third die pad 45 extends to both ends of the sealing resin 7 in the y direction, where the end on the y1 side in the y direction is exposed from the third side surface 75 and the end on the y2 side in the y direction is exposed from the fourth side surface 76. In the present embodiment, the insulating element 13 is mounted on the third die pad 45.

In the present embodiment, the third die pad 45 extending to both ends of the sealing resin 7 in the y direction does not allow a discharge portion 9 having a third portion 93 to be disposed as in the first embodiment. Each discharge portion 9 includes a first portion 91, a second portion 92, and a wire 94. The first portion 91 and the second portion 92 are shaped and arranged in the same manner as in the first embodiment, but are separate members that are not connected by the third portion 93 and are spaced apart from each other. The wire 94 is a connecting member for electrically connecting the first portion 91 and the second portion 92, and has one end electrically bonded to the first portion 91 and the other end electrically bonded to the second portion 92. The number of wires 94 is not particularly limited.

The semiconductor device A30 according to the present embodiment also includes the discharge paths 99 each including a discharge portion 9, thereby preventing a voltage not less than the dielectric withstand voltage V1 which is higher than the creeping discharge voltage V3 from being applied to the insulating element 13. Further, the semiconductor device A30 has a configuration in common with the semiconductor device A10, thereby achieving the same advantages as the semiconductor device A10. Further, according to the present embodiment, each discharge portion 9 includes a wire 94. The wire 94 bypasses the third die pad 45, and is electrically bonded to the first portion 91 and the second portion 92. This allows the discharge portion 9 to electrically connect the first portion 91 and the second portion 92 to each other via the wire 94 even when the third die pad 45 is arranged. Note that the discharge portion 9 may electrically connect the first portion 91 and the second portion 92 by using a metal plate instead of the wire 94, where the metal plate is formed to bypass the third die pad 45 and is electrically bonded to the first portion 91 and the second portion 92.

First variation:

FIGS. 19 and 20 are views for describing a semiconductor device A31 according to a first variation of the third embodiment. FIG. 19 is a partially enlarged plan view showing the semiconductor device A31, and corresponds to FIG. 17. In FIG. 19, the sealing resin 7 is shown in phantom for convenience of understanding. FIG. 20 is a cross-sectional view showing the semiconductor device A31, and corresponds to FIG. 18. The semiconductor device A31 is different from the semiconductor device A30 in the configuration of each discharge portion 9.

In the present variation, each of the discharge portions 9 further includes an insulating layer 95, an electric element 96, and a wire 97. The insulating layer 95 is made of an insulating material, and is formed on the surface of the first portion 91 facing the z1 side in the z direction. The insulating layer 95 may be an insulating bonding member that is applied and cured, or may be an insulating sheet, for example. The insulating layer 95 is arranged to insulate the electric element 96 from the first portion 91. The electric element 96 is a resistive element, for example, and is arranged on the insulating layer 95. The wire 97 is a connecting member for electrically connecting the electric element 96 and the first portion 91, and has one end electrically bonded to one terminal of the electric element 96 and the other end electrically bonded to the first portion 91. The number of wires 97 is not particularly limited. In the present variation, one end of the wire 94 is electrically bonded to another terminal of the electric element 96, instead of the first portion 91. This allows the first portion 91 and the second portion 92 to be electrically connected to each other via the electric element 96.

In the present variation, the first portion 91 and the second portion 92 are electrically connected to each other via the electric element 96 which is a resistive element. This makes it possible to suppress the current flowing through the discharge path 99 (the discharge portion 9) during creeping discharge. As such, the semiconductor device A30 can prevent a large current from flowing through the discharge path 99 during creeping discharge and affecting an element or a circuit disposed in the vicinity. The insulating layer 95 and the electric element 96 may be arranged on the second portion 92 or the third die pad 45. The electric element 96 is not limited to a resistive element, and may be another electric element such as a diode.

### Second Variation:

FIGS. 21 and 22 are views for describing a semiconductor device A32 according to a second variation of the third embodiment. FIG. 21 is a partially enlarged plan view showing the semiconductor device A32, and corresponds to FIG. 17. In FIG. 21, the sealing g resin 7 is shown in phantom for convenience of understanding. FIG. 22 is a cross-sectional view showing the semiconductor device A32, and corresponds to FIG. 18. The semiconductor device A32 is different from the semiconductor device A30 in the configuration of each discharge portion 9.

In the present variation, each of the discharge portions 9 is a single member including a third portion 93 instead of a wire 94. The third portion 93 has a U-shape as viewed in the y direction, and has a first portion extending in the x direction and second portions extending from the respective ends of the first portion to the z2 side in the z direction. The third portion 93 has one end connected to the end of the first portion 91 on the yl side in the y direction and the other end connected to the end of the second portion 92 on the y1 side in the y direction. In the present variation, each of the discharge portions 9 can also electrically connect the first portion 91 and the second portion 92 to each other via the third portion 93 that bypasses the third die pad 45.

### Fourth Embodiment

FIG. 23 is a view for describing a semiconductor device A40 according to a fourth embodiment of the present disclosure. FIG. 23 is a plan view showing the semiconductor device A40, and corresponds to FIG. 2. For convenience of understanding, FIG. 23 shows the sealing resin 7 in phantom, and the outline of the sealing resin 7 is indicated by an imaginary line (two-dot chain line). The semiconductor device A40 of the present embodiment is different from the semiconductor device of the first embodiment in not including the first semiconductor element 11 or the second semiconductor element 12. The configurations and operations of the other elements in the present embodiment are the same as those in the first embodiment. It should be understood that the fourth embodiment may include any of the elements described in the first to third embodiments and the variations described above in any combination.

In the present embodiment, the semiconductor device A40 does not include the first semiconductor element 11 or the second semiconductor element 12. Further, the semiconductor device A40 does not include the second die pad 4 or the wires 61 and 62. Only the insulating element 13 is mounted on the first die pad 3. The wires 63 are electrically bonded to the respective pad portions 53, and the wires 64 are electrically bonded to the respective pad portions 55.

The semiconductor device A40 according to the present embodiment also includes the discharge paths 99 each including a discharge portion 9, thereby preventing a voltage not less than the dielectric withstand voltage V1 which is higher than the creeping discharge voltage V3 from being applied to the insulating element 13. Further, the semiconductor device A40 has a configuration in common with the semiconductor device A10, thereby the achieving same advantages as the semiconductor device A10. The semiconductor device A40 may further include the first semiconductor element 11 (the control element), the second semiconductor element 12 (the drive element), or another element. The insulating element 13 may incorporate a circuit having the functions of the control element or a circuit having the functions of the drive element. As can be understood from the present embodiment, the elements to be mounted are not limited except for the insulating element.

The first to fourth embodiments have described an example where each of the discharge paths 99 includes a discharge portion 9, but the present disclosure is not limited to this example. Each of the discharge paths 99 may be formed without a discharge portion 9. For example, a discharge path 99 may be formed by modifying a portion of the surface of the sealing resin 7 so that creeping discharge is easily generated. In this case, the discharge path 99 is formed by the creeping discharge at the surface of the sealing resin 7, including the modified portion of the surface of the sealing resin 7. It suffices for the discharge path 99 to be configured to energize the first terminals 51 and the second terminals 52 at a voltage that is the potential difference between the input-side circuit and the output-side circuit lower than the dielectric withstand voltage of the insulating element 13.

The semiconductor device according to the present disclosure is not limited to the embodiments described above. Various design changes can be made to the specific configurations of the elements of the semiconductor device of the present disclosure. The present disclosure includes the embodiments according to the following clauses.
Clause 1.
A semiconductor device comprising:
   an insulating element (13);
a conductive member (2) including a first terminal (51) and a second terminal (52) that are electrically connected to the insulating element;
   a sealing resin (7) including a resin first surface (73) from which the first terminal protrudes, and a resin second surface (74) that faces away from the resin first surface in a first direction (x direction) perpendicular to a thickness direction (z direction) of the insulating element and from which the second terminal protrudes; and
   a discharge path (99) that is a conductive path between the first terminal and the second terminal, and that is electrically conductive at a voltage lower than a dielectric withstand voltage of the insulating element.
Clause 2.

The semiconductor device according to clause 1, further comprising a discharge portion (9) exposed from the sealing resin and insulated from the conductive member,
wherein the discharge path includes the discharge portion and a path formed by creeping discharge at a surface of the sealing resin between the discharge portion and each of the first terminal and the second terminal.
Clause 3.
The semiconductor device according to clause 2, wherein the discharge portion includes a first portion (91) and a second portion (92) that are exposed from the sealing resin and electrically connected to each other.
Clause 4.
The semiconductor device according to clause 3, wherein the discharge portion is a single member, and includes the first portion, the second portion, and a third portion (93) connected to the first portion and the second portion and covered with the sealing resin.
Clause 5.
The semiconductor device according to clause 3, wherein the first portion and the second portion are spaced apart from each other.
Clause 6. (Third embodiment, FIGS. 16 to 18)
The semiconductor device according to clause 5, wherein the discharge portion includes a connecting member (94) electrically bonded to the first portion and the second portion.
Clause 7. (First variation of third embodiment, FIGS. 19 and 20)

The semiconductor device according to clause 5, wherein the discharge portion includes an electric element (95) electrically connected to the first portion and the second portion.
Clause 8.

The semiconductor device according to clause 7, wherein the electric element is a resistive element.
Clause 9.
The semiconductor device according to any of clauses 3 to 8, wherein the sealing resin includes a resin third surface (75, 76, 71, 72) located between the resin first surface and the resin second surface, and the first portion and the second portion are exposed from the resin third surface.
Clause 10.
The semiconductor device according to clause 9, wherein the resin third surface faces in a second direction (y direction) perpendicular to the thickness direction and the first direction.
Clause 11. (Second and third variations of first embodiment, FIGS. 11 and 12)
The semiconductor device according to any of clauses 3 to 8, wherein one of the first portion and the second portion is exposed from one of the resin first surface and the resin second surface.
Clause 12.
The semiconductor device according to any of clauses 1 to 11, further comprising:
   a control element (11) electrically connected to the insulating element; and
   a drive element (12) electrically connected to the insulating element.
Clause 13.
The semiconductor device according to clause 12, wherein the conductive member includes:
   a first die pad (3) on which the control element is mounted; and
   a second die pad (4) spaced apart from the first die pad and on which the drive element is mounted.
Clause 14.
The semiconductor device according to clause 13, wherein the insulating element is mounted on the first die pad.
Clause 15. (Third embodiment, FIGS. 16 to 22) The semiconductor device according to clause 13, wherein the conductive member further includes a third die pad (45) spaced apart from the first die pad and the second die pad and on which the insulating element is mounted.

### REFERENCE NUMERALS

A10, A11, A12, A13, A14: Semiconductor device
A20, A30, A31, A32, A40: Semiconductor device
11: First semiconductor element 11A: Electrode
12: Second semiconductor element 12A: Electrode
13: Insulating element 13A: First electrode
13B: Second electrode 2: Conductive support member
3: First die pad 31: First obverse surface
32: First reverse surface 4: Second die pad
41: Second obverse surface 42: Second reverse surface
45: Third die pad 51, 51a, 51b: First terminal
53: Pad portion 54: Connecting portion
52, 52a, 52b: Second terminal 55: Pad portion
56: Connecting portion 61, 62, 63, 64: Wire
7: Sealing resin 71: Top surface
72: Bottom surface 73: First side surface
731: First area 732: Second area
733: Third area 74: Second side surface
741: Fourth area 742: Fifth area
743: Sixth area 75: Third side surface
751: Seventh area 752: Eighth area
753: Ninth area 76: Fourth side surface
761: Tenth area 762: Eleventh area
763: Twelfth area 9: Discharge portion
9a: Exposed surface 91: First portion
91a: Exposed surface 92: Second portion
92a: Exposed surface 93: Third portion
94, 97: Wire 95: Insulating layer
96: Electric element 99: Discharge path
81: Lead frame 81A: Obverse surface
81B: Reverse surface 811: Outer frame
812A: First die pad 812B: Second die pad
813: First lead 814: Second lead
815: Connecting portion 816: Dam bar
817: Discharge portion

1. A semiconductor device comprising:
an insulating element;
a conductive member including a first terminal and a second terminal that are electrically connected to the insulating element;
a sealing resin including a resin first surface from which the first terminal protrudes, and a resin second surface that faces away from the resin first surface in a first direction perpendicular to a thickness direction of the insulating element and from which the second terminal protrudes; and
a discharge path that is a conductive path between the terminal and the second terminal, and that is first electrically conductive at a voltage lower than a dielectric withstand voltage of the insulating element.

2. The semiconductor device according to claim 1, further comprising a discharge portion exposed from the sealing resin and insulated from the conductive member,
wherein the discharge path includes the discharge portion and a path formed by creeping discharge at a surface of the sealing resin between the discharge portion and each of the first terminal and the second terminal.

3. The semiconductor device according to claim 2, wherein the discharge portion includes a first portion and a second portion that are exposed from the sealing resin and electrically connected to each other.

4. The semiconductor device according to claim 3, wherein the discharge portion is a single member, and includes the first portion, the second portion, and a third portion connected to the first portion and the second portion and covered with the sealing resin.

5. The semiconductor device according to claim 3, wherein the first portion and the second portion are spaced apart from each other.

6. The semiconductor device according to claim 5, wherein the discharge portion includes a connecting member electrically bonded to the first portion and the second portion.

7. The semiconductor device according to claim 5, wherein the discharge portion includes an electric element electrically connected to the first portion and the second portion.

8. The semiconductor device according to claim 7, wherein the electric element is a resistive element.

9. The semiconductor device according to claim 3, wherein the sealing resin includes a resin third surface located between the resin first surface and the resin second surface, and
the first portion and the second portion are exposed from the resin third surface.

10. The semiconductor device according to claim 9, wherein the resin third surface faces in a second direction perpendicular to the thickness direction and the first direction.

11. The semiconductor device according to claim 3, wherein one of the first portion and the second portion is exposed from one of the resin first surface and the resin second surface.

12. The semiconductor device according to claim 1, further comprising:
a control element electrically connected to the insulating element; and
a drive element electrically connected to the insulating element.

13. The semiconductor device according to claim 12, wherein the conductive member includes:
a first die pad on which the control element is mounted; and
a second die pad spaced apart from the first die pad and on which the drive element is mounted.

14. The semiconductor device according to claim 13, wherein the insulating element is mounted on the first die pad.

15. The semiconductor device according to claim 13, wherein the conductive member further includes a third die pad spaced apart from the first die pad and the second die pad and on which the insulating element is mounted.
